(19) United States
(12) Patent Application Publication
(10) Pub. No.: US 2025/0071886 A1
(43) Pub. Date: Feb. 27, 2025

(54) INSULATION OF COMPONENTS ON A PRINTED CIRCUIT BOARD

(71) Applicant: Lisa Dräxlmaier GmbH, Vilsbiburg (DE)

(72) Inventors: Krzysztof MURGOTT, Unterschleissheim (DE); Stephan SCHAFFERHANS, München (DE); Stefan HAGENAUER, Altheim (DE)

(73) Assignee: Lisa Dräxlmaier GmbH, Vilsbiburg (DE)

(21) Appl. No.: 18/811,196

(22) Filed: Aug. 21, 2024

(30) Foreign Application Priority Data
Aug. 22, 2023 (DE) 10 2023 122 411.5

(51) Int. Cl. H05K 1/02; H05K 1/18; H05K 3/28

(52) U.S. Cl. CPC H05K 1/0256; H05K 1/181; H05K 1/189; H05K 3/284; H05K 2201/10151

(57) ABSTRACT

A device for isolating an electronic component including a printed circuit board, an electronic component positioned on a surface of the printed circuit board, and a stiffening element positioned on the surface of the printed circuit board. The stiffening element is positioned so as to at least partially surround the electronic component. The stiffening element is positioned to isolate the electronic component from an environment.

### CROSS-REFERENCE TO RELATED APPLICATIONS

This application claims priority to and the benefit of DE 10 2023 122 411.5 filed on Aug. 22, 2023. The disclosure of the above application is incorporated herein by reference.

### FIELD

The present disclosure relates to a device for insulating an electronic component on a printed circuit board, a method for producing insulation for an electronic component on a printed circuit board, and use of the device in an electric vehicle.

### BACKGROUND

The statements in this section merely provide background information related to the present disclosure and may not constitute prior art.

In order to maintain certain functions of components that are attached or soldered onto a printed circuit board, for example, these components must be electrically insulated from the environment by using insulation material. The insulation material can be a hardening material. This insulation material can run during the application of the insulation material, thereby cross-linking and insulating unintended areas. This unintended effect creates process uncertainties. For example, components with correspondingly large spacing tolerances must be placed on the printed circuit board. This means that it is important to consider the distance to which the insulation material runs from the component to be insulated. Furthermore, there can be different layer thicknesses of the insulation material on the component and the printed circuit board, which can lead to a lower insulation strength. Also, the use of viscous insulation material can lead to a tendency for bubbles to form in the insulation material itself. Bubbles in the insulation material can lead to partial discharges, meaning the insulation material may have issues over the life of the component. With the appropriate application of the insulation material, some of the electronic components may not be pressed on directly, although this would be desired for improved heat flow between the component and the printed circuit board.

Various ways exist to counteract this, such as generating barriers for the insulation material, inserting printed components, embedding sensors in the printed circuit board or using pre-formed insulating printed circuit boards or film. These various options usually incorporate additional processes and additional material, which significantly increases the amount of work and working hours. In addition, these options often result in lower measurement accuracy of the electronic component and also create increased tolerances in component positioning. In the current state of the art, additional complex manufacturing and/or processing steps often have to be provided and/or lower measurement accuracy has to be accepted.

### SUMMARY

This section provides a general summary of the disclosure and is not a comprehensive disclosure of its full scope or all of its features.

The present disclosure provides improved insulation of an electronic component on a printed circuit board, thereby at least partially solving the above-mentioned issues.

The described models apply equally to the method for producing insulation of an electronic component on a printed circuit board (or circuit board), as well as the device for insulating an electronic component on a printed circuit board and for the use of the device. Synergetic effects can arise from various combinations of the models, even if they are not described in detail.

According to one aspect of the present disclosure, a device for isolating an electronic component is provided, which has a printed circuit board, an electronic component arranged on a surface of the circuit board, a stiffening element that is configured and arranged to at least partially surround the electronic component, whereby the stiffening element is arranged on a surface of the circuit board, whereby the stiffening element is configured and arranged to isolate the electronic component from an environment.

In other words, the device has a circuit board, an electronic component arranged on the circuit board, a stiffening element that partially surrounds the electronic component, and whereby the stiffening element acts as an insulator/insulation that partially insulates the electronic component. The electronic component and the stiffening element are arranged on a surface of the circuit board, whereby both elements are arranged on the same surface of the circuit board, i.e. on the same area of the circuit board. The stiffening element surrounds the electronic component at least partially, whereby at least one or more sides can be surrounded by the electronic component. For example, a lower-most surface of the electronic component is open in the direction of the circuit board so that contact can be made with the circuit board. Furthermore, the stiffening element can be open on one or more sides around the electronic component so that these sides are freely accessible. However, this does not preclude completely surrounding the electronic component. Additional possible examples are explained below.

Isolating the electronic component from an environment can be understood, among other things, to mean that the electronic component is isolated from other electronic components that are arranged on or near the circuit board, or are located there. It can also be understood to mean that the electronic component is isolated from other electronic potentials that are generated by other electronic components such as, for example a stranded conductor in an electric car. In particular, the environment of the electronic component is an environment of the circuit board that is exposed to electronic or magnetic influences from other components and would thus influence the electronic component. The electronic component must be protected from these influences via the insulation according to the present disclosure, and their influences on the electronic component are to be reduced, to, for example, provide a higher degree of measurement accuracy to the electronic component.

The device according to the present disclosure can thus provide insulation of the electronic component using simple structural means. This means that tolerances to component boundaries can be more easily maintained and thus for the design and attachment of electronic components, better, i.e. smaller, tolerance ranges can be selected and implemented. For example, insulated components can be positioned closer to the edge of the flexible circuit board. At the same time, the height of the stiffening element can more easily provide the height of the cover above the electronic component. The selected stiffening element can beneficially increase the choice of material for the insulation material meaning it is no longer limited to a viscous insulation material, but, for example, ambient air can also be used as insulation material. A further advantage of the device according to the present disclosure is that the stiffening element can simultaneously be used as a mechanical fastening element of the circuit board, for example for a flexible circuit board, a so-called FPC. This also enables the circuit board or the flexible circuit board in particular to be pressed directly onto the encapsulated, insulated electronic component using a soft component. This is explained in more detail below.

The stiffening element surrounds the electronic component at least partially in such a way that the electronic component can come into contact with the circuit board despite the (partial) insulation via the stiffening element. In particular, the stiffening element surrounds the electronic component all around the side surfaces of the electronic component, i.e. a top side and/or the opposite bottom side are not surrounded by the electronic component, meaning they are clear of the stiffening element. The stiffening element is arranged at a distance from the electronic component, with the size of the stiffening element being adapted to the electronic component and the location of use and the desired insulation properties. This provides that the electronic component can easily be arranged as the device is being manufactured.

In one of the present disclosure examples, the stiffening element can have a recess in which the electronic component can be positioned. In particular, the recess can surround the electronic component at least on one or more side surfaces. The recess can allow access to the electronic component from above, so that the electronic component can be easily positioned as the device is being manufactured. The recess can be adapted to the shape of the electronic component, i.e. the recess can be rectangular, square, oval or round, although it does not have to be limited to a specific shape.

In one example of the present disclosure, the recess can extend from one side of the stiffening element to a second side that is opposite the first side of the stiffening element. In other words, the recess can extend through the stiffening element, with the recess at least partially surrounding the electronic component. The recess can, for example, be a type of hole through the stiffening element, the hole extending to the surface of the printed circuit board on which the electronic component is positioned perpendicularly and/or at a defined angle. For example, angled side surfaces can also be used if a conical milling cutter is used to produce the recess. In other words, the stiffening element can extend in a vertical direction away from the surface of the printed circuit board on which the component is positioned. Extension in a vertical direction is not limited to a precise vertical, i.e. right-angled extension, i.e. the stiffening element can also extend obliquely, meaning it can be angled in a vertical direction away from the printed circuit board.

In one example of the present disclosure, the stiffening element can surround the electronic component on at least one or more side surfaces of the electronic component where the side surfaces extend in a perpendicular direction or at a defined angle to the surface on which the electronic component is positioned on the printed circuit board. This provides that the component is accessible to the insulating material above and that the stiffening element can serve as a barrier for the insulating material on the sides of the electronic component. If the recess is designed as a type of hole, the recess, and thus the stiffening element as well, completely surround the electronic component on its sides. Conversely, the recess can also be designed as a lateral recess on the stiffening element, so that the recess is open to the surroundings of the printed circuit board on at least one side. An example thereof, a U-shaped recess. The shape of the recess and which sides of the electronic component are surrounded by the recess are not limited to the specific models indicated above. Depending on the application, the recess and its structural shape can be selected accordingly.

In one example of the present disclosure, the printed circuit board can be a multilayer circuit board. The multilayer circuit board can, for example, include at least one base layer, one top layer and one or more electrically conductive layers, whereby one or more electrically conductive layers are positioned between the base layer and the top layer. The layers of the printed circuit board are not limited to the arrangement mentioned above. Depending on the desires of the printed circuit board and the electronic component to be positioned on it, more or fewer layers can also be provided.

In one example of the present disclosure, the electrically conductive layer can, for example, be a copper layer, whereby the electrically conductive layer is not limited to this specific material. This means that other corresponding conductive materials can also be used for the electrically conductive layer.

In one example of the present disclosure the component can be positioned on the top layer and in particular the component can be connected to the electrically conductive layer by the top layer. The component can also be positioned on the base layer and connected to the electrically conductive layer by the base layer. In the device according to the present disclosure, the electrically conductive layer is provided, for example, for contact with the electronic component. The top layer can thus be correspondingly recessed, i.e. it can be exposed during a manufacturing process of the printed circuit board so that the electrically conductive layer is exposed and available and provided in the area in which an electronic component is provided, for affixing the electronic component, e.g. by means of soldering. On the other hand, other contacts, such as wires, pins or similar, can also extend from the electrically conductive layer through the base/top layer in order to connect the electrically conductive layer to the electronic component.

In one example of the present disclosure, the electronic component can be a sensor, and in particular it can be a temperature sensor that will detect thermal sources in the vicinity of the device. With the aid of the structure of the device, a sensor that is located very close to the edge of a printed circuit board, such as, for example, a flexible circuit board, can be precisely insulated electrically with the aid of insulating material, such as a Glop top. The recess inhibits the insulating material from running and an undefined layer thickness above the sensor can be avoided. For example, a temperature sensor as an electronic component in the device according to the present disclosure can provide very high dynamics of the measurable temperature of an external surface. The surface to be measured can have a high voltage potential that is electrically insulated from the sensor by the printed circuit board, or, in particular, by the flexible circuit board and the stiffening element and/or insulating material and hardly influences its measurement.

In one example of the present disclosure, the printed circuit board is a flexible circuit board. In particular, the circuit board is a so-called FPC. On thicker circuit boards there are longer thermal paths before the heat under the printed circuit board reaches the electronic component, such as, for example, a temperature sensor. This means that rapid temperature changes are hardly detected or recorded. The dynamic behavior of the temperature sensor is therefore limited based on the thickness of the circuit board. This means that short paths track the dynamics of the temperature fluctuations. This can be solved by using a flexible circuit board as its layer structure is thinner.

In one example of the present disclosure, the device can further include a force-applying element which is positioned on the stiffening element and configured to apply force to the stiffening element so that the device can be pressed in the direction of an element to be measured. A mechanical force can be introduced via the force-applying element without affecting the electronic component, such as a sensor, or the insulation material that is positioned very close to the sensor. This mechanical force introduction can be applied directly next to the sensor or directly above the sensor via the stiffening element. The sensor does not experience any mechanical forces because the force is applied directly to the stiffening element. This force-free mechanical pressing of a sensor onto a defined surface with simultaneous electrical insulation using an insulation material is a specific state which enables improved insulation of the sensor and at the same time improved measurement accuracy and improved positioning options for the sensor. With the force-applying element the device according to the present disclosure can be pressed in the direction of an element to be measured, such as a surface or another external component. The force-applying element can be attached, i.e. fastened to the stiffening element in a force-fitting, form-fitting or material-fitting manner.

For example, a mechanical force can be introduced into the stiffening element by means of a force-fitting connection, whereby the device is brought in the direction of a component to be measured. This leads, for example, to a zero gap being created to a thermal source to be measured, as the element to be measured can be created, which increases the measurement accuracy when a temperature sensor is used as an electronic component.

For example, one or more screws, one or more rivets, one or more mechanical springs, or one or more bending clamps can be provided as a force-applying element. The elements mentioned here are only examples and do not have to be limited to them. Any element that can generate force can be used in the device according to the present disclosure. For example, a screw connection of the element to be stiffened on a surface to be measured or at another location in the environment can serve as a force-transmitting element. Furthermore, a spring-loaded element that is supported on a housing or on another element in the environment of the device on which the device is positioned can be used and thus transmit force to the stiffening element. Furthermore, the use of hot caulking similar to riveting the stiffening element onto a surface to be measured is also possible and/or a connection with locking hooks or a similar device for a mechanical form fit can be used as a force-applying element.

In one example of the present disclosure, force can be applied perpendicularly to the element to be stiffened by the force-applying element. In other words, the force to be applied can always have at least one perpendicular component that is aligned with the element to be stiffened. This can provide an exact positioning of the electronic component relative to the element to be measured.

In one example of the present disclosure, the electronic component can be positioned a slight distance from an edge of the printed circuit board, whereby the distance is in particular in a range of 0.5 mm to 30 mm, and more precisely in a range of 0.5 mm to 10 mm. With the device according to the present disclosure and its positioning on the printed circuit board and the stiffening element and the electronic component in relation to one another, the electronic component can thus be positioned closer to an edge of the printed circuit board. This results in, for example, better accessibility for the electronic component and also material savings since the printed circuit board could be made smaller. The distance of the electronic component from the edge of the printed circuit board depends, for example, on the insulation of the electronic component and/or on the method of manufacture of the stiffening element.

In one example of the present disclosure, the stiffening element can further comprise an insulating material which is configured and positioned to insulate the electronic component from the environment. This additional insulating material can further increase the insulating properties of the device according to the present disclosure.

In one example of the present disclosure, the insulating material can at least partially surround the electronic component. This accordingly insulates the electronic component from the external environment. In particular, the insulating material surrounds the electronic component from the side and from above. This means that the electronic component remains free of insulating material at least on the side with which it comes into contact with the printed circuit board or on the side with which it is positioned on the surface of the board.

In one example of the present disclosure, the insulating material can be positioned in the recess and can at least partially fill the recess. In other words, the recess can be completely and/or only partially filled by the insulating material. This means that the electronic component can be partially and/or completely surrounded by the insulating material and thus covered by the insulating material.

In one example of the present disclosure, the insulation material can be a liquid insulation material and/or a viscous insulation material and/or a hardening insulation material. Advantageously, the use of the stiffening element, which can serve as a barrier for the insulation material, does not limit one to a specific insulation material. The stiffening element can increase the choice of materials for the insulation material, but insulation material with other fluid properties can be used. Furthermore, when liquid material is used, the stiffening element can inhibit the liquid material from running. Furthermore, when liquid insulation material is used, the tendency for bubbles to form in the insulation material can be reduced compared to viscous insulation material, which in turn reduces partial discharges within the bubbles and increases the insulation capacity over the lifetime. With the present device, thin-liquid insulation material can now also be used, thus significantly improving the insulation properties. This improves the insulation properties of the device according to the present disclosure overall.

At the same time, the height of the insulation material covering the electronic component can be more easily provided based on the height of the stiffening element as it relates to the recess. The improved application and positioning of the insulation material above the electronic component provides that the height of the insulation material above the electronic component is consistent and that bending and the associated different layer thicknesses of the insulation material are reduced. This also improves the insulation properties of the device according to the present disclosure with regard to the risk of high voltage and arcing on the printed circuit board.

In one example of the present disclosure, the insulating material can completely fill the recess of the stiffening element and/or the component is completely surrounded by the insulating material on the sides and above the electronic component. For example, the insulating material surrounds the electronic component on a top side and, if it is a rectangular electronic component, on all four side surfaces of the electronic component, so that only the bottom of the electrical component remains clear, and the electronic component can come into contact with the printed circuit board or with the electrically conductive layer in particular, on this bottom side. For example, the insulating material can also be a so-called Glop top.

According to one aspect of the present disclosure, the device according to one of the described examples can be used to isolate an electronic component in a charging pad of an electric vehicle. In particular, the device can be used in a charging socket, whereby the charging socket can be the interface of an electric vehicle to, for example, an external charging station or socket. In particular, the device can be used in a charging pad from a charging infrastructure to an electrical energy storage device in an electric vehicle.

According to one aspect of the present disclosure, the device according to the present disclosure can, for example, be positioned in a charging socket. According to this example application, temperature sensors on a flexible circuit board are pressed down on the pin plates of charging socket pins using the stiffening element. This provides the thermal path from the pin plate to the temperature sensor. The high-voltage potential of the charging pins is effectively isolated from the temperature sensor by the flexible circuit board and the insulation material. The surface of the stiffening element makes the mechanical adjustment very easy. In this example, the mechanical pressure can be created by screwing the inner part to a piece of the charging socket's housing.

According to another aspect of the present disclosure, a method for isolating an electronic component on a printed circuit board is provided where the method is comprised of these steps: providing a printed circuit board; applying a stiffening element to a surface of the printed circuit board which at least partially surrounds the electronic component; arranging an electronic component on the surface of the printed circuit board whereby the stiffening element isolates the electronic component from the environment.

Other possible steps with which the method can be supplemented include, for example, introducing or creating a recess in the stiffening element, providing a force-applying element which is positioned on the stiffening element, providing a conductive contact between the circuit board and the electronic component. It should be noted that the method can be supplemented through method steps similar to the examples described above as they relate to the device.

Furthermore, it should be noted that all examples of the present disclosure relating to a method can be carried out in the described order. Nevertheless, this need not be the only possible and desired order in the method. The methods described herein can be carried out in a different order than that disclosed without deviating from the corresponding example of the method, unless the opposite is expressly stated below.

The printed circuit board used in the device according to the present disclosure and the method according to the present disclosure can include a prefabricated printed circuit board or a flexible circuit board in particular. The method can include upstream steps which encompass populating the flexible circuit board until the desired flexible circuit board has been manufactured. The steps described above can then be carried out.

In the present case, an electronic component is understood to mean any component that can be attached to a printed circuit board. In particular this refers to electronic components with which the properties of the environment and/or the printed circuit board and/or the components themselves, or those of other components can be measured. Non-exhaustive examples of this are include temperature sensors, strain gauges, piezo elements and heating surfaces.

It should be noted that more than one electronic component can also be used in the device according to the present disclosure. The stiffening element is accordingly adapted in terms of its shape and design so that, for example, depending on the number of components, the corresponding number of recesses and insulation material are provided in the stiffening element, whereby the number of components and the number of recesses depend on the selected example.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic perspective view of a device according to a model of the present disclosure;

FIG. 2 is a schematic cross-sectional view of an example device according to a form of the present disclosure; and

FIG. 3 is a schematic enlarged cross-sectional view of the example device from FIG. 2.

The figures are merely schematic representations and only serve to explain the present disclosure. Identical or equivalent elements are provided with the same reference numerals throughout.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

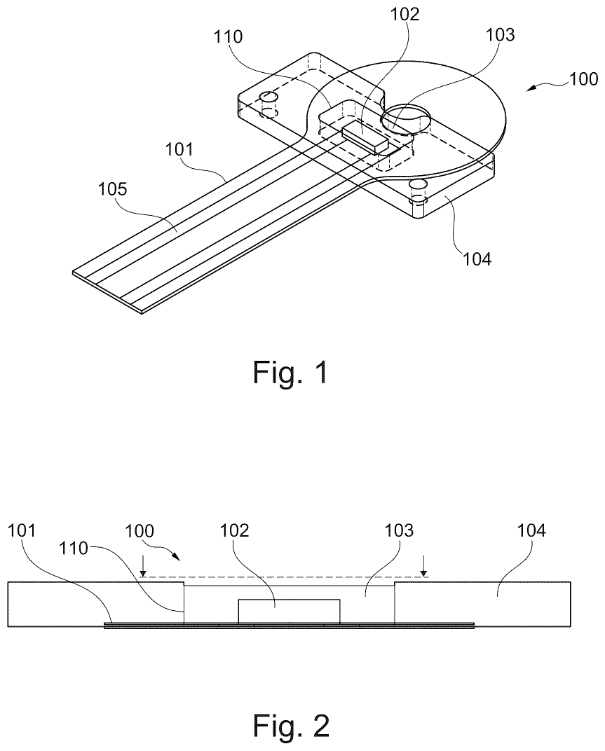

FIG. 1 shows a schematic representation of a sectional view of example device 100 according to a form of the present disclosure. The device 100 for isolating an electronic component 102 comprises: a printed circuit board 101, an electronic component 102 arranged on a surface of the printed circuit board 101, a stiffening element 104 which is configured and positioned to at least partially surround the electronic component 102, whereby the stiffening element 104 is positioned on the surface of the printed circuit board 101. Furthermore, the device 100 comprises an insulating material 103 which is configured and positioned to insulate the electronic component 102 from the environment. This insulating material 103 can also be omitted, so that only the stiffening element 104 serves to act as insulation for electronic component 102. As can be seen from FIG. 1, electronic component 102 is positioned within the recess 110 and is surrounded by the stiffening element 104 to be stiffened on at least the side surfaces which extend perpendicular to the surface on which the electronic component 102 is attached to the printed circuit board 101. This means that the electronic component 102 is accessible from above. In particular, the insulating material 103 can be applied to the electronic component 102 from above, so that the insulating material 103 is also located within the recess 110 of the stiffening element 104 to be stiffened. In one example the insulating material 103 surrounds the electronic component 102 laterally and from above. The electronic component is in contact with or connected to the electrically conductive layer 105. According to this example, two electrically conductive layers 105 are positioned parallel to one another in a plane in order to form corresponding conductor tracks to the electronic component 102. The electronic component 102 is, for example, a rectangular temperature sensor, the shape of the recess 110 being adapted to the temperature sensor or electronic component 102. The insulation material 103 almost completely fills the recess 110, especially in such a way that a surface of the insulation material 103 which is opposite the surface of the printed circuit board 101 is on the same plane as the surface of the stiffening element 104. In the schematic example shown here, the recess 110 and thus also the stiffening element 104 surrounds the electronic component 102 on four sides. This means that the top and bottom of the electronic component 102 are cut out and are not surrounded by the recess 110, or the stiffening element 104.

FIG. 2 shows a schematic representation of a sectional view of an example device 100 according to a form of the present disclosure. In this figure, it can be seen that the insulating material 103 is not completely introduced up to the upper edge of the stiffening element 104, meaning it only partially fills the recess 110. However, the insulating material 103 covers the electronic component 102 from the top and from the side surfaces perpendicular to the top of the printed circuit board 101. The dashed line in FIG. 2 shows the force to be applied, which can be generated by means of the examples described here relating to the force-applying element. For example, a screw can be screwed into the stiffening element 104, wherein the screw can be positioned close to the recess 110. In one example the example device 100 is configured to be pressed in a direction of an element to be measured.

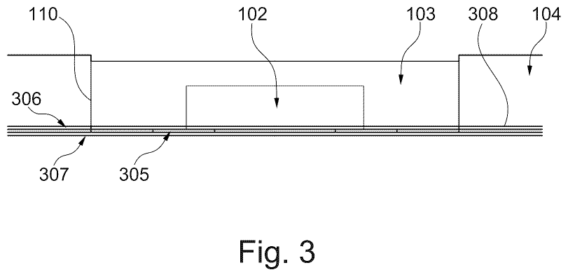

FIG. 3 shows a schematic representation of an enlarged sectional view of the example device 100 from FIG. 2. In particular, FIG. 3 is enlarged so as to show that the individual layers of the printed circuit board 101 can be seen. In this example, this is a multilayer printed circuit board 101 which includes at least three layers. These three layers are the base layer 307, the top layer 306 with a surface 308, and the electrically conductive layer 305 which lies between these two layers. Depending on the example selected, printed circuit board 101 can also be comprised of more than three layers and the positioning of the electrically conductive layer 305 can differ from the positioning shown. In one example the printed circuit board 101 is a flexible circuit board.

In one example, at least one side surface of the electronic component 102 extends at a defined angle or in a vertical direction to a surface of the printed circuit board 101 on which the electronic component 102 is arranged. In another example the electronic component 102 is arranged a short distance from an edge of the printed circuit board 101. In one example the short distance is between 0.5 mm and 30 mm. In another example the short distance is between 0.5 mm and 10 mm. In yet another example the example device 100 is configured to be used in a charging pad of an electrically powered vehicle.

Although the present disclosure has been illustrated and broken down in detail in the drawings and the above description, these drawings and descriptions must be understood to be merely illustrative or examples and are not to be considered limiting. The present disclosure is not limited to the disclosed examples. Professional and experts skilled in this area will be able to understand and make use of the claimed present disclosure based on the drawings, disclosure, and dependent claims.

In addition, it should also be noted that “comprising” does not exclude other elements or steps, and “a” or “an” does not exclude a plurality. Furthermore, it should also be noted that features or steps described with reference to one of the above examples may also be used in combination with other features or steps of other examples described above. Reference symbols in the claims are not to be considered limiting.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A device for isolating an electronic component, the device comprising:
a circuit board;
the electronic component arranged on a surface of the circuit board; and
a stiffening element arranged on the surface of the circuit board and configured to at least partially surround the electronic component, and the stiffening element is configured to isolate the electronic component from an environment.

2. The device according to claim 1, wherein the stiffening element includes a recess, the electronic component is arranged in the recess of the stiffening element, the recess extends from a first side of the stiffening element to a second side of the stiffening element, and the second side of the stiffening element is opposite the first side of the stiffening element.

3. The device according to claim 2, wherein the stiffening element includes an insulating material that is configured to insulate the electronic component from the environment, and the insulating material surrounds the electronic component laterally and from above.

4. The device according to claim 3, wherein the insulating material is arranged in the recess of the stiffening element and at least partially fills the recess of the stiffening element.

5. The device according to claim 1, wherein the stiffening element surrounds at least one side surface of the electronic component, the at least one side surface extending at an angle to a surface of the circuit board on which the electronic component is arranged.

6. The device according to claim 1, wherein the circuit board is a multilayer circuit board including at least one base layer, a top layer and one or more electrically conductive layers, the one or more electrically conductive layers are arranged between the at least one base layer and the top layer.

7. The device according to claim 6, wherein the electronic component is arranged on the top layer and the electronic component is connected to the one or more electrically conductive layers via the top layer.

8. The device according to claim 6, wherein the electronic component is arranged on the at least one base layer and wherein the electronic component is connected to the one or more electrically conductive layers via the at least one base layer.

9. The device according to claim 1, wherein the electronic component is a sensor, and the circuit board is a flexible circuit board.

10. The device according to claim 9, wherein the sensor is a temperature sensor.

11. The device according to claim 1, wherein the circuit board is a flexible circuit board.

12. The device according to claim 1, further comprising a force-applying element arranged on the stiffening element, the force-applying element is configured to apply force to the stiffening element so that the device is pressed in a direction of an element to be measured.

13. The device according to claim 1, wherein the electronic component is arranged a short distance from an edge of the circuit board, and the short distance is between 0.5 mm to 30 mm.

14. The device according to claim 13 wherein the short distance is between 0.5 mm to 10 mm.

15. The device according to claim 1 wherein the device is configured to be associated with a charging pad of an electrically powered vehicle.

16. A method for isolating an electronic component on a circuit board, the method comprising:
preparing a circuit board;
applying a stiffening element to a surface of the circuit board which at least partially surrounds the electronic component; and
arranging the electronic component on the surface of the circuit board and the stiffening element is configured to isolate the electronic component from an environment.
